(19) United States
(12) Patent Application Publication
(10) Pub. No.: US 2015/0236733 A1
(43) Pub. Date: Aug. 20, 2015

(54) METHOD AND APPARATUS FOR IMPROVING AUDIO RECEPTION IN A PAGING DEVICE

(71) Applicant: MOTOROLA SOLUTIONS, INC., Schaumburg, IL (US)

(72) Inventors: FAZAL BALOCH, STREAMWOOD, IL (US); MATTHEW D. BUSA, PLANTATION, FL (US); STEVEN J. ENGEL, CARY, IL (US); RUSSELL R. JOHNSON, DEKALB, IL (US)

(73) Assignee: MOTOROLA SOLUTIONS, INC., Schaumburg, IL (US)

(21) Appl. No.: 14/181,090

(22) Filed: Feb. 14, 2014

(51) Int. Cl. H04B 1/10; H03G 3/34

(52) U.S. Cl. CPC H04B 1/10; H03G 3/344

(57) ABSTRACT

A method (300) and apparatus (200) are provided for operating a portable pager. The method and apparatus eliminate channel noise between paging tones and voice messages. Channel noise is squelched between paging tones and voice messages using a delayed N timer, thereby allowing the speaker to remain on. Paging tones are received and played at the speaker during a signaling squelch mode of operation. The detection of the paging tones and subsequent drop in carrier signal, initiates a timer during which channel noise is squelched during a carrier squelch mode of operation. The timer is delayed (delay N timer) so as to expire only after the carrier frequency is re-established. Once the carrier signal is re-established followed by the delayed timer expiration, the carrier squelch is removed. The speaker remains on during both signaling squelch and carrier squelch. Hence, paging tones are heard, channel noise is silenced, and then voice messages are played.

### FIELD OF THE DISCLOSURE

The present invention relates to paging devices and, more particularly, to reducing channel noise in such devices.

### BACKGROUND

A paging device is typically a portable, receive only, voice communication device. Paging devices were originally developed in the 1970's to address the need for a portable radio small enough to be worn by a person and only activated when needed. Paging devices continue to be utilized today and are oftentimes carried by fire and rescue personnel as well as other agencies, such as utilities and private contractors. Paging devices advantageously offer a small, compact form factor that can be carried on a person and usually left on a silent “standby” mode. When the unit is activated, the pager sounds a tone or vibrating alert at the pager's speaker, followed by an announcement from a dispatcher alerting the user of a situation. After activation, the pager remains in an “open” position much like a scanner, and continuously broadcasts any audio transmissions on that channel until the unit is reset back into a silent “standby” mode (depending on programming selections) or it resets back to the “standby” mode after a set amount of time. A pager is a receive-only unit, not a transceiver, and thus cannot transmit.

During typical pager operation, when an incoming radio frequency (RF) carrier is present on a channel, the speaker is turned on while the message/page is being recorded and played out. Having both the speaker and page recording active when the carrier drops results in a condition called open channel noise. Open channel noise can be considered annoying to some users.

Accordingly, it would be desirable to have a paging device that would eliminate the open channel noise condition.

### BRIEF DESCRIPTION OF THE FIGURES

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 is a timing diagram for a paging device operating in accordance with various embodiments;

FIG. 2 is a block diagram of a paging device operating in accordance with various embodiments;

FIG. 3 is a method for improving audio reception in a paging device in accordance with various embodiments; and

FIG. 4 is a paging device in accordance with various embodiments.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION

Briefly, there is provided herein a method and apparatus for operating a paging device to eliminate channel noise in the absence of a carrier signal. In accordance with the various embodiments, channel noise is squelched between paging tones and voice messages using a delayed N timer, thereby allowing the pager's speaker to remain on (active). The paging device operating in accordance with the various embodiments provides improved audio reception for the user by eliminating irritating noise that in past devices could be heard after the paging tone and prior to the voice message being heard.

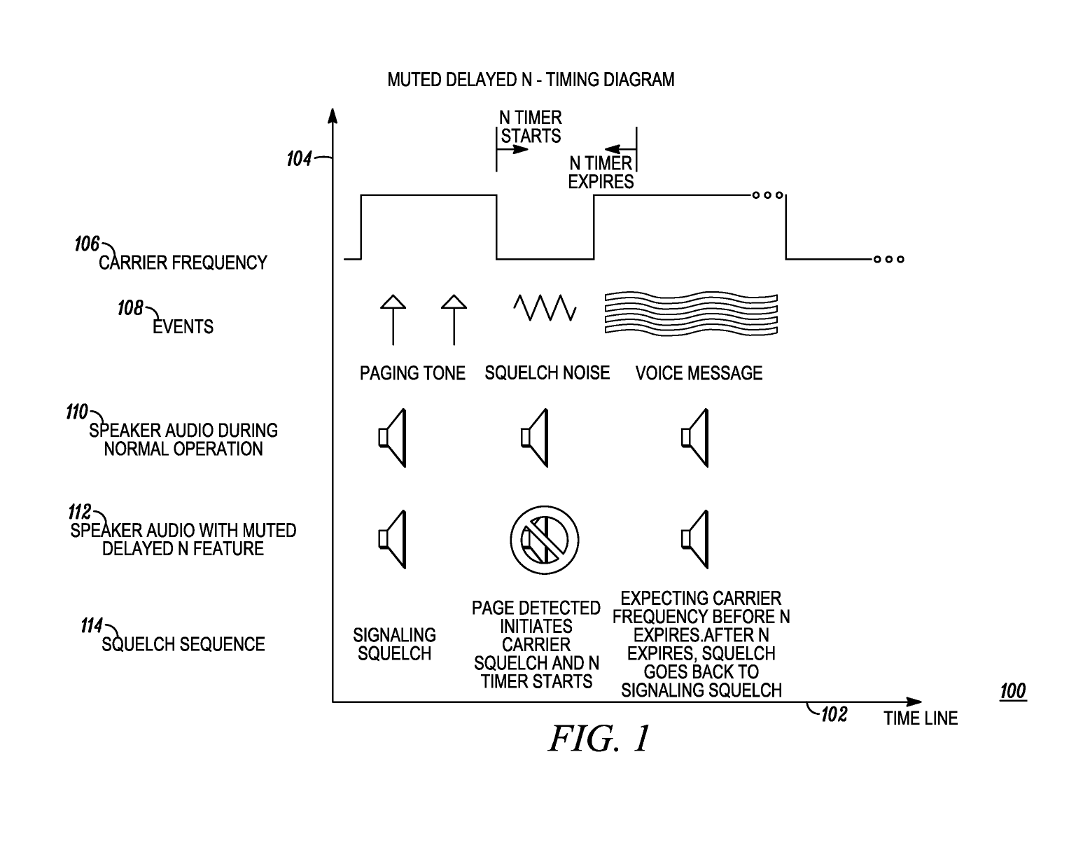

Referring to FIG. 1, there is shown a timing diagram 100 for a pager incorporating muted delayed N timer operation in accordance with the various embodiments. The horizontal axis represents time 102 while the vertical axis 104 represents various paging operational parameters. The various operational parameters are illustrated in accordance with an incoming page being received including: a carrier frequency 106, events 108 (paging tones, channel noise, voice message), speaker audio during normal/past operation 110, speaker audio with muted delayed N feature, and squelch sequence 114. In accordance with the various embodiments, the speaker remains active (on) throughout the reception of a page.

During initial reception of a page, the pager utilizes signaling squelch to permit the receiver's audio to open only in the presence of a predetermined programmed RF carrier frequency and predetermined correct audio tone(s). Thus, when a predetermined RF carrier is received having a predetermined paging tone sequence, the pager's speaker plays out an alert tone corresponding to the audio tones. The alert tone may be an audio alert or a vibrating alert.

After the alert tones have been played out, the carrier frequency drops but the pager remains on channel which causes channel noise to be generated. With past pagers, this channel noise would be played out at the speaker thereby causing an annoying noise to be heard by the user. Applying a muted delayed N timer, in accordance with the various embodiments, allows the channel noise to be squelched (or silenced) in response to the carrier being dropped. For the purposes of this application, the delayed N timer is a timer (N) that is started when the RF carrier drops. The term muted delayed N timer is used to represent the muting function of the channel noise and squelching sequence being delayed for N seconds by the timer. The RF carrier re-establishment is expected before the N timer expires. Expiration of the N timer or the next RF carrier drop will change the squelching sequence. In FIG. 1, the event 108 labeled “squelch noise” represents the squelching (or silencing) of the channel noise. Detection of an incoming page initiates carrier squelch. Carrier squelch operation mutes all audio when the carrier on the RF frequency the pager is programmed to receive drops.

When the RF carrier is re-established and the voice message appears it can be played (and/or recorded) immediately because the speaker has remained on (active). In accordance with the embodiments, the delayed N timer (during which time carrier squelch takes place) only expires after the carrier frequency is re-established. Once the timer has expired and RF carrier frequency has dropped, the squelch sequence returns to signaling squelch, which as stated previously, only opens audio paths in response to a predetermined programmed RF carrier frequency and predetermined correct audio tone(s). Thus, both a predetermined RF carrier and predetermined paging tones are required for a new page.

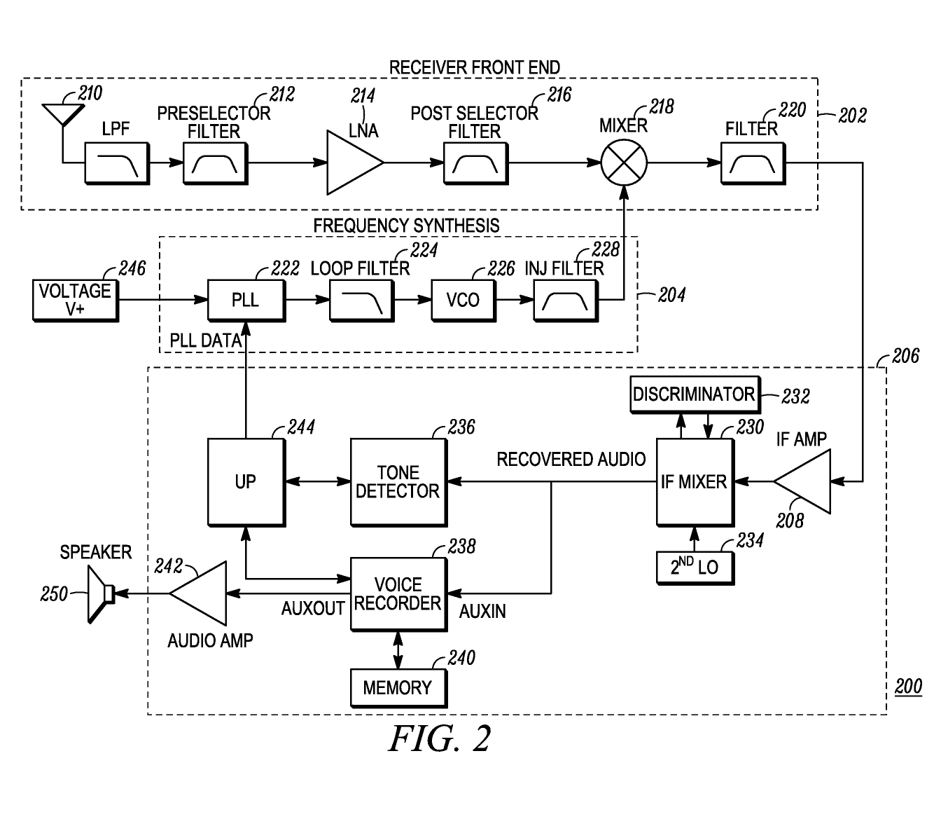

FIG. 2 is a block diagram of a paging device 200 formed and operating in accordance with various embodiments. In accordance with the various embodiments, pager 200 advantageously eliminates channel noise in the absence of a carrier signal during an incoming page. Paging device 200 comprises various sections including a receiver front end 202, frequency synthesis section 204, and controller section 206. The various sections are powered, directly or indirectly, by voltage supply 246 and are controlled directly or indirectly by a microprocessor 244. A general operation of the pager 200 will first be described with the understanding that fewer or additional components may be utilized as understood by those skilled in the art.

In general, the receiver front end 202 comprises the circuitry between an antenna 210 and a first intermediate frequency (IF) stage 208. The RF front end 202 processes an incoming radio frequency (RF) signal, before it is converted to a lower intermediate frequency (IF). The RF front end 202 can generally be described as comprising a plurality of filters, amplifiers and at least one mixer. For example, in this embodiment receiver front end 202 comprises the antenna 210 (for receiving the RF signal), a preselector filter 212 (for rejecting out-of-band interference), a low noise amplifier 214 (for increasing the sensitivity of the receiver), a post selector filter 216 (for additional filtering), and a mixer 218 (for mixing the incoming signal with a local oscillator (LO) signal generated from the frequency synthesis section 204). The output of the mixer 218 is filtered at filter 220 to convert the signal to the intermediate frequency (IF). Other front end configurations may also be used.

As mentioned previously, the LO signal is generated through frequency synthesis section 204. In general, the frequency synthesis section 204 comprises a phase lock loop 222 (providing a frequency oscillator and phase detector), loop filter 224, voltage control oscillator 226 (producing an LO frequency), and injection filter 228 (for filtering and the LO signal prior to application to mixer 218).

Once the mixer and local oscillator signals are down converted to an intermediate (IF) signal, the IF signal is then processed through the controller section 206 to recover audio which is ultimately played out at a speaker 250. Controller section comprises an IF amplifier 208 (for generating amplified IF signal), IF mixer 230 (for mixing the amplified IF signal with a second LO signal 234 and signal levels detected by discriminator 232) thereby generating recovered audio. The recovered audio signal is passed through a tone detector 236 and, if applicable, a voice recorder 238 for recording a voice message. The recorded voice message is stored in a memory 240, which may be a temporary or flash memory. The voice message is amplified at audio amplifier 242 prior to being played out at speaker 250.

As discussed previously, as incoming pages are received the pager 200 generate channel noise between the paging tones and the voice message which can be annoying to a user. In accordance with the various embodiments, the pager 200 eliminates this channel noise through the use of a timer, a delayed N timer which is incorporated within the microprocessor 244. In operation, the receiver section 202 receives a radio frequency (RF) carrier signal and converts the RF carrier signal to an intermediate frequency (IF) signal. The controller section 206 converts the IF signal into recovered audio signals, the recovered audio signals initially comprise paging tones. The speaker plays alert tones corresponding to the paging tones. A signaling squelch mode of operation occurs during the incoming paging tones. Signalizing squelch mode, controlled by microprocessor 244, permits the receiver's audio to open only in the presence of a predetermined programmed RF carrier frequency and predetermined correct paging tone(s).

Once the alert has been played and the RF carrier drops, channel noise would have been heard on past devices. However, the microprocessor 244 operating in accordance with the various embodiments starts the delayed N timer for squelching the channel noise generated in response to the RF carrier signal being dropped. Squelch is a circuit function controlled by microprocessor 244 that acts to suppress the audio output of a receiver in the absence of a sufficiently strong desired input signal. The muted delayed N timing is provided by the microprocessor 244 and provided as an input to the IF mixer 230 to squelch channel noise at the recovered audio output of the IF mixer. The timer is set to remain on (carrier squelch) until after the RF carrier is re-established. In accordance with the various embodiments the delayed N timer only expires after the carrier signal has been re-established with the voice message.

While some past communication systems have utilized a muted “revert” N timer to suppress channel noise, the muted revert N does not require paging tones once the carrier drops after time N. Unfortunately, this allows the user to hear all audio, even unwanted, being transmitted on the programmed channel. The muted delay N, on the other hand, provides the advantage of, once the carrier drops after N has expired, paging tones are required to unmute voice on a detected carrier frequency. The muted delayed N thus ensures the user does not have to hear unwanted audio being transmitted on the programmed channel. The muted delayed N operation requires no extra components to the overall pager since the microprocessor 244 provides the timing control.

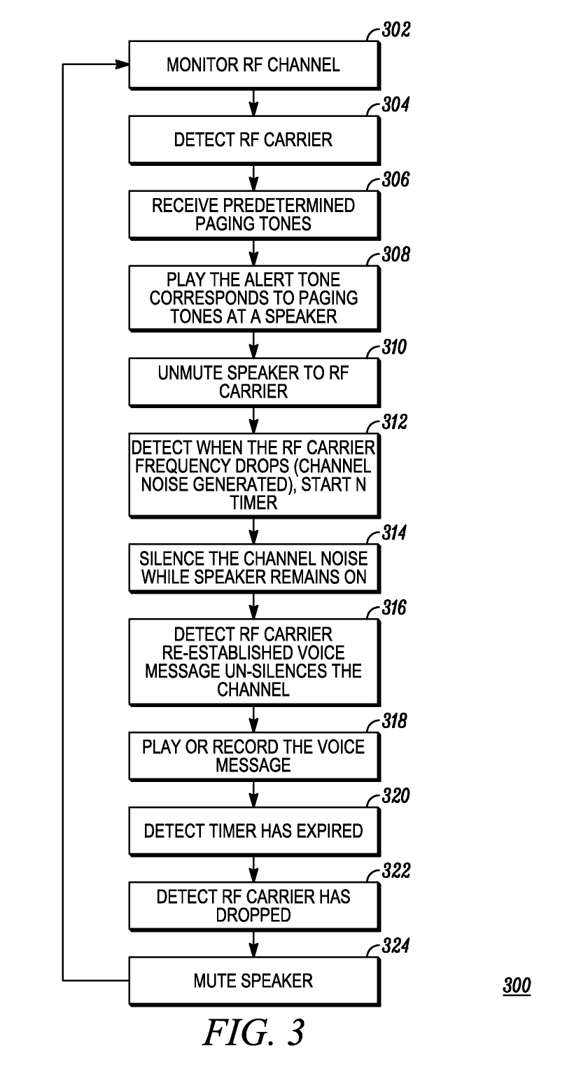

FIG. 3 is a method 300 for controlling audio at a pager in accordance with the various embodiments. Method 300 beings at 302 by monitoring an RF channel. Depending on the pager configuration more than one RF channel may be monitored. At 304, an RF carrier frequency is detected, carrying predetermined paging tones. An alert tone is played at 308 at a speaker of the pager which corresponds to the predetermined paging tones. The playing of the alert tone at the speaker is done during the signaling squelch mode of operation which only permits the audio if the predetermined paging tones are sent over the predetermined RF carrier frequency.

At 310, un-muting of the speaker to the RF carrier frequency occurs. At 312, a timer is started (the delayed N timer) when the pager detects that the RF carrier frequency has dropped—once the carrier frequency has dropped channel noise will be present. The channel noise is silenced at 314 (via the controller as previously discussed) while the speaker remains on. The silencing of the channel noise is done during the carrier squelch mode of operation. The carrier squelch mode of operation is enabled in response to detecting a page, the page comprising the predetermined paging tones and the predetermined RF carrier frequency.

At 316, the pager detects that the RF carrier is re-established and un-silences the channel at which point the message can be heard. At 318, the pager begins to play and/or record the voice message. At 320, the pager detects that the timer has expired. At 322, the RF carrier has dropped (voice message is complete). The speaker is muted at 324 and the pager returns to monitor the RF channel at 302. To un-mute the speaker, paging tones and proper carrier are required.

Method 300 advantageously allows the speaker to remain active/on while silencing channel noise between incoming pager tones and subsequent voice messages. Again, the expiration of the squelching sequence is delayed by the timer N, as was shown in FIG. 1. Without the delay users would hear annoying channel noise.

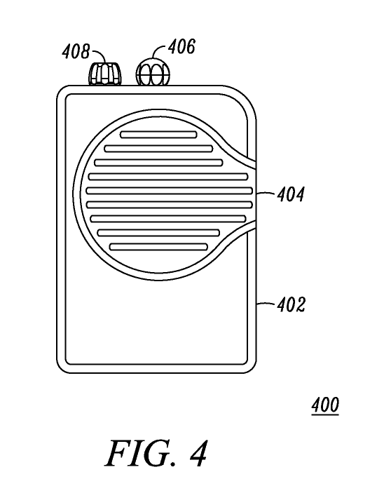

FIG. 4 is a paging device 400 formed and operating in accordance with various embodiments. Pager 400 is a portable battery powered device comprising a housing 402, speaker 404, volume control knob 406 and channel control knob 408. Housing 402 has electronic components such as those described in FIG. 2 contained therein. Pager 400 may be programmed to operate over VHF Low Band, VHF High Band, or UHF frequency ranges. Pager operation comprises standby and active modes. Pager 400 can play and record voice messages after the pager activates.

In accordance with the various embodiments, pager 400 will activate when a particular series of audible tones are sent over the frequency (commonly referred to as a “page”) the pager is set to. For example, if pager 400 is programmed on VHF frequency channel 155.295 MHz and set to alert for 879 Hz & 358.6 Hz, it will disregard any other tone sequences transmitted on that frequency, only alerting when the proper sequence has been received. In accordance with the various embodiments, the pager provides delayed N timer operation for squelching channel noise generated in response to the RF carrier signal being dropped in between paging tones and the voice message, the delayed N timer only expiring after the carrier signal has been re-established with the voice message. Expiration of the N timer or the next RF carrier drop will change the squelching sequence from carrier squelch back to signaling squelch. The pager may be reset back into its standby mode by pressing the reset button, or it can be programmed to reset back into the standby mode automatically after a predetermined amount of time, to conserve battery power.

Pager 400 scan at least one channel and may also be programmed to scan two channels by selecting that function via a rotary knob on the pager; in this mode the user will hear all traffic, even without the correct tones being sent. If the activation tones are transmitted in this “open” position, the pager alerts as normal. Pager 400 may have the option to remain “open” or “closed” when scanning two channels. Pager 400 may also be programmed to simultaneously scan up to two channels and have multiple activation tones. Multi-channel scan can be helpful if a user belongs to several emergency services, or the emergency service has different alarms for different emergencies. Pager 400 can also record, over a predetermined amount of time, a voice/transmission after the pager activates. A repeater (not shown) may be used to improve paging coverage, as it can be located for better range than a dispatch center where the page originates from.

Accordingly, there has been provided a pager with improved audio reception. The timer operation of the muted delayed N timer is completely embodied in the receiver without any need for adjustments to power supplies and without any additional components. The control of the timing function mutes the audio between incoming tones and the actual message itself The message is expected within N seconds after the tones are received, otherwise paging tones will be required to be sent again. The muted delayed N is a beneficial feature to pagers that mutes annoying channel noise when carrier drops momentarily before the message follows.

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

It will be appreciated that some embodiments may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

We claim:

1. A method for controlling audio at a pager, comprising:
monitoring at least one radio frequency (RF) channel;
detecting a predetermined radio frequency (RF) carrier frequency on a monitored RF channel;
receiving predetermined paging tones over the RF carrier frequency;
playing an alert tone at a speaker of the pager, the alert tone corresponding to the predetermined paging tones;
un-muting the speaker to the RF carrier carrier frequency;
detecting when the RF carrier frequency drops, thereby generating channel noise, and starting a timer;
silencing the channel noise and starting a timer while the speaker remains on;
detecting the RF carrier frequency is re-established, the RF carrier now carrying a a voice message that un-silences the channel;
playing or recording the voice message;
detecting when the timer has expired;
detecting when the RF carrier carrying the voice message drops; and
muting the speaker prior to returning to monitoring.

2. The method of claim 1, wherein the predetermined paging tones comprise audible tones or vibrating tones.

3. The method of claim 1, wherein the pager is a portable, battery operated paging device.

4. The method of claim 1, further comprising:
continuing to play the voice message after the timer has expired;
dropping the RF carrier once the voice message is complete; and
returning to monitoring the at least one RF channel.

5. The method of claim 1, wherein playing the predetermined paging tones at a speaker of the pager is done during a signaling squelch mode of operation which only permits the predetermined paging tones over the predetermined RF carrier frequency.

6. The method of claim 5, wherein silencing the channel noise is done during a carrier squelch mode of operation.

7. The method of claim 6, wherein the carrier squelch mode of operation is enabled in response to detecting a page, the page comprising the predetermined paging tones and the predetermined RF carrier frequency.

8. A pager, comprising:
a receiver; and
a controller for controlling the receiver, the controller initiating carrier squelch operation upon detection of a predetermined radio frequency (RF) carrier frequency with predetermined paging tones, the carrier squelch operation remaining active for a predetermined time and remaining active when the predetermined RF carrier frequency is dropped and channel noise is generated, the carrier squelch operation silencing the channel noise, the predetermined time only expiring after the RF carrier frequency is re-established, and voice messages carried over the re-established RF carrier being played at speaker or recorded while the channel noise remains squelched.

9. The pager of claim 8, wherein the pager operates in a signaling squelch operation upon receipt of the paging tones, the signaling squelch operation playing the receiver's audio only in the presence of the predetermined RF carrier frequency and predetermined paging tones.

10. The pager of claim 9, wherein the pager returns to signaling squelch operation upon drop of the re-established RF carrier.

11. The pager of claim 9, wherein the speaker remains on throughout the signaling squelch operation and the carrier squelch operation.

12. The pager of claim 8, wherein both the predetermined RF carrier and the predetermined paging tones are required to receive a new page.

13. The pager of claim 8, wherein the pager is a portable, battery operated paging device.

14. A pager, comprising:
a receiver section for receiving a radio frequency (RF) carrier signal and converting the RF carrier signal to an intermediate frequency (IF) signal;
a controller section for converting the IF signal into recovered audio signals, the recovered audio signals comprising paging tones and voice messages;
a speaker for playing alert tones corresponding to the paging tones and subsequently playing the voice message; and
the controller controlling a delayed N timer for squelching channel noise generated in response to the RF carrier signal being dropped in between paging tones and the voice message, the delayed N timer only expiring after the carrier signal has been re-established with the voice message.

15. The pager of claim 14, wherein the delayed N timer starts after the paging tones and RF carrier drop.

16. The pager of claim 14, wherein the squelch operation comprises carrier squelch operation.

17. The pager of claim 16, wherein the pager is in a signaling squelch mode of operation while the paging tones are being received prior to carrier squelch operation.

18. The pager of claim 17, wherein the pager returns to the signaling squelch mode of operation when the RF carrier carrying the voice message is dropped.

19. The pager of claim 15, wherein the speaker remains on during signaling the signaling squelch mode of operation and the carrier squelch mode of operation.

20. The pager of claim 15, wherein the controller mutes the recovered audio signals during carrier squelch, and carrier squelch operates for a predetermined time set by the delayed N timer.
